(19) United States
(12) Patent Application Publication
(10) Pub. No.: US 2023/0242393 A1
(43) Pub. Date: Aug. 3, 2023

(54) MICROMECHANICAL COMPONENT AND MANUFACTURING METHOD FOR A MICROMECHANICAL COMPONENT FOR A SENSOR OR MICROPHONE DEVICE

(71) Applicant: Robert Bosch GmbH, Stuttgart (DE)

(72) Inventors: Heribert Weber, Nuertingen (DE); Andreas Scheurle, Leonberg (DE); Peter Schmollngruber, Aidlingen (DE); Thomas Friedrich, Moessingen-Oeschingen (DE)

(21) Appl. No.: 18/043,374

(22) PCT Filed: Aug. 18, 2021
(86) PCT No.: PCT/EP2021/072887

§ 371 Date: Feb. 28, 2023

(30) Foreign Application Priority Data
Sep. 8, 2020 (DE) 10 2020 211 232.0

(51) Int. Cl. B81B 3/00; B81C 1/00

(52) U.S. Cl. CPC B81B 3/0086; B81B 3/001; B81C 1/00968; B81C 1/00698; B81B 2201/0228; B81B 2201/0257; B81B 2201/0264; B81B 2203/04; B81C 2201/0105; B81B 2201/0221

(57) ABSTRACT

A micromechanical component for a sensor or microphone device. An electrode surface of a first electrode structure is aligned with a second electrode structure. A substructure of the first electrode structure is entirely made of at least one electrically conductive material. The electrode surface and an opposite surface of the first electrode structure are outer surfaces of the substructure. A stop structure protruding from the electrode surface towards the second electrode structure is formed on the first electrode structure. The first electrode structure includes an insulating region which extends from the electrode surface to the opposite surface of the first electrode structure. The stop structure is formed either as a projection of the at least one insulating region protruding from the electrode surface towards the second electrode structure or is bordered by the at least one insulating region.

### FIELD

The present invention relates to a micromechanical component for a sensor or microphone device. The present invention also relates to a manufacturing method used for a micromechanical component for a sensor or microphone device.

### BACKGROUND INFORMATION

German Patent Application No. DE 10 2006 055 147 A1 describes a sound transducer structure having a membrane and having a counter electrode designed such that a distance between the membrane and the counter electrode is variable by sound waves impacting on the membrane. Stop structures are formed on the counter electrode, which are covered by a silicon oxynitride layer having a low oxygen content and are intended to prevent adhesion of the membrane to the counter electrode as well as a charge transfer between the membrane that is in contact with the stop structures and the counter electrode.

### SUMMARY

The present invention provides a micromechanical component for a sensor or microphone device and a manufacturing method used for a micromechanical component for a sensor or microphone device.

The present invention provides micromechanical components in which a stability of the at least one stop structure of their first electrode structure is improved over the related art. Despite the improved stability of the at least one stop structure, an occurrence of an electrical short circuit between the first electrode structure and the associated second electrode structure of the same micromechanical component is reliably prevented. The micromechanical components provided by the present invention therefore have an advantageously long service life.

In an advantageous embodiment of the micromechanical component of the present invention, at least one insulating region is entirely made of the at least one electrically insulating material, which in each case has an electrical conductivity of less than 10⁻⁸ S/cm and a resistance of greater than 10⁸ Ω·cm. As a result, there is little or no need to fear the occurrence of an electrical short circuit between the respective first electrode structure and the second electrode structure interacting therewith in the same micromechanical component, even in case of an overload.

For example, the at least one insulating region can be at least partially made of silicon nitride, silicon dioxide, silicon oxynitride, silicon carbide, undoped silicon, and/or undoped germanium, germanium oxide, germanium nitride, germanium oxynitride, germanium carbide, aluminum oxide, and/or another metal oxide as the at least one electrically insulating material. Thus, the conventional materials already frequently used in semiconductor technology can be advantageously employed as the at least one electrically insulating material. This facilitates the manufacturability of the micromechanical component and helps reduce the manufacturing costs thereof.

In particular, the at least one insulating region may in each case be shaped such that the respective insulating region at least partially surrounds a core structure made of at least one electrically insulating and/or electrically conductive material.

By way of the choice of the material of the at least one insulating region, the at least one insulating region may perform another function in addition to its electrically insulating function, e.g., that of an etch stop layer. By way of the choice of the material of the least one insulating and/or electrically conductive material of the core structure, the core structure may perform also another function, e.g., that of an etch stop layer and/or a conducting path layer.

In an advantageous example embodiment of the manufacturing method of the present invention, the following substeps are performed: forming the second electrode structure, depositing at least one sacrificial material layer on a side of the second electrode structure later to be aligned with the first electrode structure, depositing at least one electrically conductive material of the future first electrode structure on the sacrificial material layer, patterning at least one recess through the at least one electrically conductive material of the future first electrode structure, which in each case extends into the sacrificial material layer, and forming the at least one stop structure and the at least one insulating region on the first electrode structure by depositing the at least one electrically insulating material in the at least one recess, whereby the at least one stop structure is in each case formed as a projection protruding from the electrode surface in the at least one insulating region. The substeps described here are already able to be performed by means of conventional processes frequently performed in semiconductor technology. Therefore, implementing the embodiment of the manufacturing method described here enables the production of at least one micromechanical component at comparatively low manufacturing costs. In addition, the substeps specified here can easily be performed at the wafer level.

In particular, the at least one electrically insulating material of the at least one stop structure and the at least one insulating region can be first deposited in the at least one recess and on at least one subarea of the opposite surface of the first electrode structure before a respective remaining volume of the at least one recess is filled with at least one electrically insulating and/or electrically conductive material of at least one core structure, wherein the at least one electrically insulating material of the at least one stop structure and of the at least one insulating region covering the at least one subarea of the opposite surface is additionally covered by the at least one second electrically insulating and/or electrically conductive material of the at least one core structure. The at least one electrically conductive material of the at least one core structure can be, e.g., silicon, doped silicon, silicon carbide, doped silicon carbide, germanium, doped germanium, a metal, a metal silicide, a metal nitride, and/or a metal oxide, e.g., indium tin oxide (ITO). In this case, not only the at least one stop structure has an advantageous stability, but rather the entire first electrode structure is additionally stabilized by the formation of the at least one core structure.

Alternatively, the at least one recess can also first be completely filled with the at least one electrically insulating material of the at least one stop structure and the at least one insulating region, which material is additionally deposited on at least a subarea of the opposite surface of the first electrode structure before at least one electrically insulating and/or electrically conductive material is deposited such that the at least one electrically insulating material of the at least one stop structure and the at least one insulating region covering the at least one subarea of the opposite surface is covered by the at least one second electrically insulating and/or electrically conductive material. Additional stabilization of the first electrode structure can also be achieved in this manner.

In a further advantageous example embodiment of the manufacturing method, the following substeps are performed:

forming the second electrode structure, depositing at least one sacrificial material layer on a side of the second electrode structure later to be aligned with the first electrode structure, patterning at least one depression in the sacrificial material layer, depositing at least one electrically conductive material of the future first electrode structure on the sacrificial material layer, thereby forming the at least one stop structure by filling the at least one depression with the at least one electrically conductive material of the future first electrode structure, patterning at least one separation trench, which in each case extends to the sacrificial material layer in such a way through the at least one electrically conductive material of the future first electrode structure that at least one partial volume made from the at least one electrically conductive material of the future first electrode structure, which partial volume is equipped with the at least one stop structure, is completely bordered by the at least one separation trench, and forming the at least one insulating region on the first electrode structure by depositing the at least one electrically insulating material in the at least one separation trench. The substeps described here can also be performed by means of standard semiconductor technology processes. The manufacture of micromechanical components at a comparatively low cost is therefore also possible by implementing the embodiment of the manufacturing method described here. The embodiment of the manufacturing method described here can also be performed advantageously at the wafer level.

As an advantageous embodiment of the present invention, the at least one electrically insulating material of the at least one insulating region can first be deposited in the at least one separation trench and on at least a subarea of the opposite surface of the first electrode structure before a remaining volume of the at least one separation trench is in each case filled with at least one electrically insulating and/or electrically conductive material of at least one core structure, whereby the at least one electrically insulating material of the at least one insulating region covering at least a subarea of the opposite surface is additionally covered by the at least one electrically insulating and/or electrically conductive material of the at least one core structure. Additional stabilization of the first electrode structure is also possible by means of the embodiment described here.

### BRIEF DESCRIPTION OF THE DRAWINGS

Further features and advantages of the present invention are explained below in reference to the figures.

FIG. 1 shows a schematic illustration of a first example embodiment of the micromechanical component of the present invention.

FIG. 2 shows a schematic illustration of a second example embodiment of the micromechanical component of the present invention.

FIGS. 3A to 3C shows schematic cross-sections for explaining a first example embodiment of a manufacturing method for a micromechanical component of the present invention.

FIGS. 4A to 4C shows a schematic cross-sections for explaining a second example embodiment of the manufacturing method of the present invention.

FIGS. 5A to 5C shows a schematic cross-sections for explaining a third example embodiment of the manufacturing method of the present invention.

### DETAILED DESCRIPTION OF EXAMPLE EMBODIMENTS

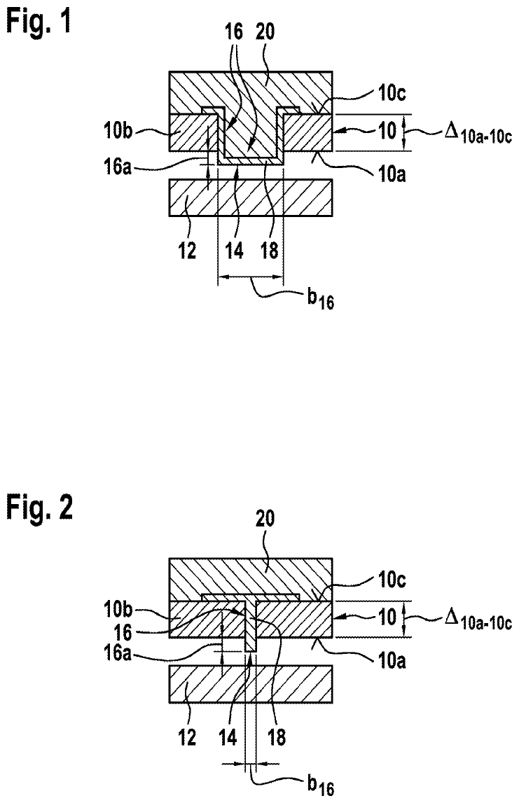

FIG. 1 is a schematic illustration of a first embodiment of the micromechanical component.

The micromechanical component shown schematically in FIG. 1 comprises a first electrode structure 10 and a second electrode structure 12. The first electrode structure 10 and the second electrode structure 12 are arranged with respect to one another such that an electrode surface 10a of the first electrode structure 10 is aligned with the second electrode structure 12. In particular, with respect to the first electrode structure 10, the second electrode structure 12 can be arranged in a direction aligned perpendicular to the electrode surface 10a of the first electrode structure 10. This can be referred to as a parallel arrangement of the second electrode structure 12 with respect to the first electrode structure 10. In addition, the first electrode structure 10 and/or the second electrode structure 12 are displaceably and/or warpably arranged/formed such that a distance between the electrode surface 10a of the first electrode structure 10 and the second electrode structure 12 is variable. The displacement/warping of the first electrode structure 10 and/or the second electrode structure 12 such that the distance between the electrode surface 10a of the first electrode structure 10 and the second electrode structure 12 is varied can be triggered for example by means of a voltage applied between the two electrode structures 10 and 12 and/or due to an external force acting on at least one of the electrode structures 10 and 12, e.g., a compression force or an acceleration force in particular.

At least one substructure 10b of the first electrode structure 10 is made entirely of at least one electrically conductive material. The electrode surface 10a of the first electrode structure 10 and an opposite surface 10c of the first electrode structure 10 oriented away from the electrode surface 10a are outer surfaces of the substructure 10b and are made of the at least one electrically conductive material. For example, the at least one electrically conductive material of the first electrode structure 10 (and/or the substructure 10b thereof) can be at least one semiconductor material and/or at least one metal, in particular at least one metal silicide, and/or at least one metal nitride, and/or at least one metal oxide, e.g., ITO. Preferably, the at least one electrically conductive material of the first electrode structure 10/its substructure 10b is silicon/polysilicon, particularly doped silicon/polysilicon. The second electrode structure 12 can also be at least partially made of the at least one electrically conductive material of the first electrode structure 10b/its substructure 10b and/or of at least one further electrically conductive material. Preferably, the second electrode structure 12 is also at least partially made of silicon/polysilicon, particularly doped silicon/polysilicon.

Formed on the first electrode structure 10 is at least one stop structure/knob structure 14 protruding from the electrode surface 10a towards the second electrode structure 12, which stop structure 14 is designed such that, in the case of a mechanical contact between the at least one stop structure 14 and the second electrode structure 12, a charge transfer between the first electrode structure 10 and the second electrode structure 12 is prevented (even if a non-zero voltage is applied between the two electrode structures 10 and 12). To this end, the first electrode structure 10 comprises at least one insulating region 16 made of at least one electrically insulating material, in each case extending from the electrode surface 10a to at least the opposite surface 10c of the first electrode structure 10, the at least one stop structure 14 being in each case formed as a projection 16a of the at least one insulating region 16 protruding from the electrode surface 10a towards the second electrode structure 12. The formation of the at least one stop structure 14 as a projection 16a of the insulating region 16 extending in each case from the respective stop structure 14 at least to the opposite surface 10c of the first electrode structure 10 results in an improved “anchoring” of the at least one stop structure 14 on the first electrode structure 10/its substructure 10b made of the at least one electrically conductive material. In the micromechanical component shown schematically in FIG. 1, a stability of its at least one stop structure 14 is thus significantly improved. The formation of the at least one stop structure 14 as a projection 16a of the insulating region 16 extending in each case from the respective stop structure 14 at least to the opposite surface 10c of the first electrode structure 10 further results in a topography-free area of uniform thickness between the first electrode structure 10 and the second electrode structure 12 in the area of the at least one stop structure 14, without the need for an additional CMP step. A surface distance Δ_{10a-10c} between the electrode surface 10a and the opposite surface 10c of the first electrode structure 10 can be chosen as desired.

The substructure 10b made of of the at least one electrically conductive material can in particular be understood as a “framework structure” framing the at least one stop structure 14 made of the at least one electrically insulating material. A maximum extent of the substructure 10b made from the at least one electrically conductive material perpendicular to the electrode surface 10a is preferably greater than or equal to 75% of the maximum extent of the second electrode structure 12 perpendicular to the electrode surface 10a, particularly greater than or equal to the maximum extent of the second electrode structure 12 perpendicular to the electrode surface 10a. This ensures a good interaction between the first electrode structure 10 and the second electrode structure 12.

The mechanical contact surface of the respective stop structure 14 with the second electrode structure 12 may be chosen as desired via a corresponding design concept. The mechanical contact surface can thus be designed to ensure a good force distribution of the force exerted by the second electrode structure 12 on the stop structure 14. Again, this helps to improve a stability of the at least one stop structure 14 on the first electrode structure 10/its substructure 10b made of the at least one electrically conductive material.

Preferably, the at least one insulating region 16 is entirely made of the at least one electrically insulating material, in each case having an electrical conductivity of less than 10⁻⁸ S/cm or a resistance of greater than 10⁸ Ω·cm. For example, the at least one insulating region 16 can be at least partially made of silicon nitride, particularly silicon-rich silicon nitride, silicon dioxide, silicon oxynitride, silicon carbide, undoped silicon, undoped germanium, germanium oxide, germanium oxynitride, germanium nitride, germanium carbide, and/or a metal oxide, e.g., aluminum oxide in particular, as the at least one electrically insulating material. However, the materials mentioned here are to be interpreted by way of example only.

In the example shown in FIG. 1, the at least one insulating region 16 in each case comprises an insulating layer 18 made of at least one electrically insulating material, which in each case surrounds a core structure 20 made of at least one electrically insulating and/or electrically conductive material. By using different materials for the insulating layer 18 and the surrounded core structure 20, manufacturing of the micromechanical component can be facilitated, as will be discussed below. Preferably, the insulating layer 18 consists of silicon-rich silicon nitride, while the core structure 20 consists of silicon dioxide and/or silicon. In addition, in the embodiment shown in FIG. 1, a minimum width b₁₆ of the at least one insulating region 16 aligned parallel with the electrode surface 10a is greater than twice the thickness of the insulating layer 18.

Optionally, the insulating layer 18 is additionally deposited on at least a subarea of the opposite surface 10c of the first electrode structure 10, while the core structure 20 also covers the insulating layer 18, which covers the at least one subarea of the opposite surface 10c, and possibly at least one further remaining surface of the opposite surface 10c not covered by the insulating layer 18. Covering at least part of the opposite surface 10c of the first electrode structure 10 by means of the insulating layer 18 and the material of the core structure 20 results in an additional “anchoring” of the stop structure 14 on the first electrode structure 10. This can also help improve the stability of the at least one stop structure 14 on the first electrode structure 10/its substructure 10b made of the at least one electrically conductive material.

FIG. 2 is a schematic illustration of a second embodiment of the micromechanical component.

The micromechanical component shown schematically in FIG. 2 differs from the above-described embodiment in that the minimum width b₁₆ of the at least one insulating region 16 is less than or equal to twice the thickness of the insulating layer 18 made of the at least one electrically insulating material. Therefore, the at least one insulating region 16 is (entirely) made of the at least one electrically insulating material of the insulating layer 18, the at least one electrically insulating material of the insulating layer 18 being additionally deposited on at least a subarea of the opposite surface 10c of the first electrode structure 10. By means of an (optional) CMP step performed after the deposition of the insulating layer 18, the surface of the insulating layer 18 can be planarized and the desired layer thickness of the insulating layer 18 can be adjusted on the opposite surface 10c of the first electrode structure 10.

The at least one electrically insulating material of the insulating layer 18 that covers at least one partial area of the opposite surface 10c, and possibly at least one remaining surface of the opposite surface 10c not covered by the insulating layer 18 is optionally also covered by at least one electrically insulating and/or an electrically conductive material of the core structure 20. In the embodiment of FIG. 2, the at least one stop structure 14 is thus also “anchored” to the opposite surface 10c of the first electrode structure 10. Therefore, the at least one stop structure 14 also exhibits good stability in the embodiment shown in FIG. 2.

With regard to further features of the micromechanical component of FIG. 2 and the advantages thereof, reference is made to the embodiment in FIG. 1 described earlier.

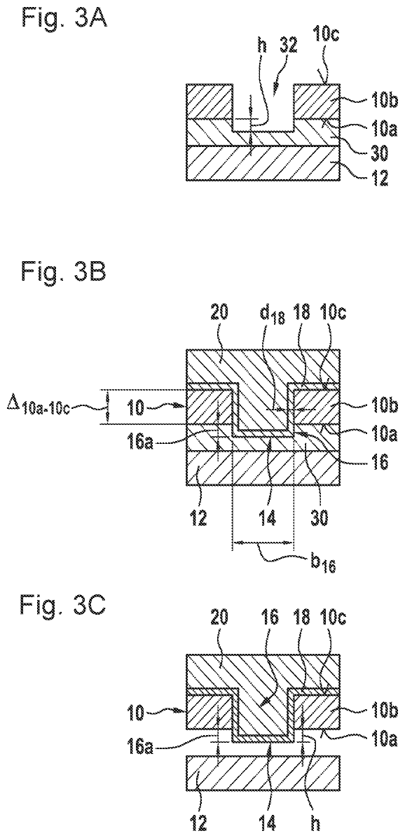

FIGS. 3A to 3C are schematic cross-sections for explaining a first embodiment of a manufacturing method for a micromechanical component.

When implementing the manufacturing method described here, a first electrode structure 10 and a second electrode structure 12 are arranged in relation to one another such that an electrode surface 10a of the first electrode structure 10 is parallel with the second electrode structure 12 and opposite the second electrode structure 12. In the example shown in FIGS. 3A to 3C, the second electrode structure 12 is first formed for this purpose. In particular, the second electrode structure 12 is arranged on a substrate (not shown) and/or on at least one intermediate layer covering the substrate (not illustrated). The second electrode structure 12 can be made of at least one electrically conductive material, e.g., at least one semiconductor material, at least one metal, at least one metal silicide, at least one metal nitride, at least one metal carbide, and/or at least one metal oxide, e.g., ITO. Preferably, the second electrode structure 12 is made of (doped) polysilicon, e.g., by the second electrode structure 12 being patterned from a (previously doped or subsequently doped) polysilicon layer.

At least one sacrificial material layer 30 is subsequently deposited on a side of the second electrode structure 12 which is later aligned with the first electrode structure 10. For example, the sacrificial material layer 30 can be made of silicon dioxide.

Subsequently, at least one electrically conductive material of the future first electrode structure 10 is deposited on the sacrificial material layer 30. For example, at least one semiconductor material, at least one metal, at least one metal silicide, at least one metal nitride, at least one metal carbide and/or at least one metal oxide, e.g., ITO, can be deposited as the at least one electrically conductive material of the future first electrode structure 10. Preferably, the first electrode structure 10 is made of (doped) polysilicon, e.g., by the first electrode structure 10 on the sacrificial material layer 30 being patterned from a (previously doped or subsequently doped) polysilicon layer.

In the manufacturing method described here, at least one stop structure 14 protruding from the electrode surface 10a towards the second electrode structure 12 is formed on the first electrode structure 10 such that, in the event of a mechanical contact between the at least one stop structure 14 and the second electrode structure 12, a charge transfer between the first electrode structure 10 and the second electrode structure 12 is prevented. Therefore, only a substructure 10b of the future first electrode structure 10 is formed entirely from its at least one electrically conductive material by patterning the substructure 10b of the future first electrode structure 10 out of the at least one electrically conductive material by means of at least one recess 32 through the at least one electrically conductive material of the future first electrode structure 10.

The electrode surface 10a of the first electrode structure 10 and an opposite surface 10c of the first electrode structure 10 oriented away from the electrode surface 10a are in this way formed as outer surfaces of the substructure 10b made of the at least one electrically conductive material.

The at least one stop structure 14 is produced by patterning at least one recess 32 by means of an etching process, which is performed starting from the opposite surface 10c of the first electrode structure 10, which is oriented away from the electrode surface 10a, and proceeds towards the sacrificial material layer 30. As will be clear from the following description, both a position and a shape of the at least one future stop structure 14 are defined by the at least one recess 32. The at least one recess 32 is in this case designed to extend in each case into the sacrificial material layer 30. A patterning depth/etching depth of the at least one recess 32 in the sacrificial material layer 30 in each case defines a future height h of the at least one stop structure 14. FIG. 3A is a schematic cross-section after the at least one recess 32 has been patterned through the at least one electrically conductive material of the future first electrode structure 10 into the sacrificial material layer 30.

FIG. 3B shows the formation of at least one insulating region 16 from at least one electrically insulating material on the first electrode structure 10 for forming the at least one stop structure 14. The formation of the at least one insulating region 16 on the first electrode structure 10 is performed by depositing the at least one electrically insulating material in the at least one recess 32. For example, silicon nitride, silicon dioxide, silicon oxynitride, silicon carbide, undoped silicon and/or undoped germanium, germanium oxide, germanium nitride, germanium oxynitride, germanium carbide, aluminum oxide and/or another metal oxide may be deposited as the at least one electrically insulating material. Entirely filling the at least one recess 32 with the at least one electrically insulating material can ensure that the at least one insulating region 16 in each case extends from the electrode surface 10a to at least the opposite surface 10c of the first electrode structure 10. In addition, the at least one stop structure 14 is in this way formed as a projection 16a of the at least one insulating region 16 in each case protruding towards the second electrode structure 12 on the electrode surface 10.

As can be seen in FIG. 3B, a minimum width of the at least one recess 32, which is aligned parallel with the electrode surface 10a of the first electrode structure 10, in each case defines a minimum width b₁₆ of the at least one insulating region 16 that is aligned parallel with the electrode surface 10a. In the embodiment shown in FIGS. 3A to 3C, the minimum width b₁₆ of the at least one stop structure 14 is greater than twice the thickness of the insulating layer 18. It is therefore expedient to first deposit an insulating layer 18 made of at least one electrically insulating material in the at least one recess 32 and on at least a subarea of the opposite surface 10a of the first electrode structure 10, a layer thickness d₁₈ of the insulating layer 18 aligned perpendicular to the electrode surface 10a being less than the minimum width b₁₆.

After the insulating layer 18 has been introduced/deposited into the at least one recess 32, a remaining volume of the at least one recess 32 not occupied by the insulating layer 18 is filled with at least one electrically insulating and/or electrically conductive material of a core structure 20, whereby the at least one electrically insulating material of the insulating layer 18 that covers at least one partial area of the opposite surface 10c, and possibly at least one remaining surface of the opposite surface 10c not covered by the insulating layer 18 is also covered by the at least one electrically insulating and/or an electrically conductive material of the core structure 20. Optionally, the at least one electrically insulating and/or electrically conductive material of the core structure 20 can subsequently be planarized by means of a chemical-mechanical polishing step. The result is shown in FIG. 3B.

FIG. 3C shows the finished micromechanical component after at least partial removal of the sacrificial material layer 30. If the sacrificial material layer 30 is composed of silicon oxide, the sacrificial material layer 30 can be at least partially removed, e.g., by an etching process, e.g., by a hydrofluoric acid (HF)-containing wet chemical or gaseous etching process in particular. To prevent undesired etching of the at least one stop structure 14, a material etch-resistant to the etching medium used to at least partially remove the sacrificial material layer 30 can be used as the at least one electrically insulating material of the insulating layer 18. For example, the insulating layer 18 can be made of silicon-rich silicon nitride, which has a high etching resistance to a wet chemical or gaseous etching process containing hydrofluoric acid. Regarding the core structure 20, silicon dioxide and/or silicon is preferred as the at least one electrically insulating and/or electrically conductive material.

It should in this context also be noted that, when implementing the manufacturing method described here, the first electrode structure 10 and/or the second electrode structure 12 are arranged/formed in a displaceable and/or warpable manner such that a distance between the electrode surface 10a of the first electrode structure 10 and the second electrode structure 12 is variable (at least after partially removing the sacrificial material layer 30). However, given that processes for displaceably arranging at least one of the electrode structures 10 and 12 and designing at least one of the electrode structures 10 and 12 to be warpable are conventional in the related art, this will not be discussed in more detail.

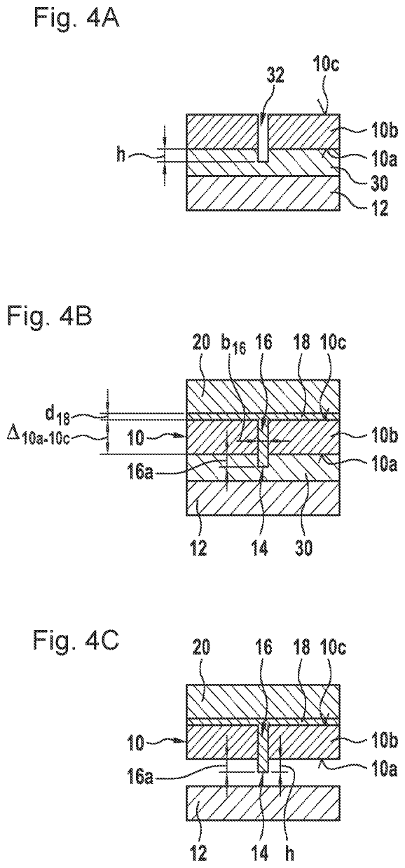

FIGS. 4A to 4C are schematic cross-sections for explaining a second embodiment of the manufacturing method.

FIG. 4A is a schematic cross-section after patterning the at least one recess 32 through a layer structure from the second electrode structure 12, the sacrificial material layer 30, and the at least one electrically conductive material of the future first electrode structure 10. The method steps performed in order to produce the intermediate product shown in FIG. 4A have already been explained in regard to FIG. 3A.

In the manufacturing method schematically illustrated by FIGS. 4A to 4C, the at least one insulating region 16 having a minimum width b₁₆ less than or equal to twice the thickness d₁₈ of the insulating layer 18 is made of the at least one electrically insulating material. For this reason, the at least one recess 32 is first completely filled with the at least one electrically insulating material of the insulating layer 18, which is additionally deposited on at least a subarea of the opposite surface 10c of the first electrode structure 10. At least one electrically insulating and/or electrically conductive material of the core structure 20 is then deposited such that the at least one electrically insulating material covering the at least one subarea of the opposite surface 10c and possibly also at least one remaining surface of the opposite surface 10c not covered by the insulating layer 18 is covered by the electrically insulating and/or electrically conductive material of the core structure 20.

FIG. 4C shows the final micromechanical component after at least partial removal of the sacrificial material layer 30. In order to be able to prevent etching of the stop structure 14 while removing at least part of the sacrificial material layer 30, silicon-rich silicon nitride is preferred as the at least one electrically insulating material of the insulating layer 18, and silicon dioxide and/or silicon is preferred as the at least one electrically insulating and/or electrically conductive material of the core structure 20.

The at least one insulating region 16 can also be completely filled with the insulating layer 18 and have a width b₁₆, which is greater than twice the thickness of the insulating layer 18 if the layer thickness d₁₈ of the insulating layer 18 is greater than the sum of the height h of the at least one stop structure 14 plus the surface distance Δ_{10a-10c} between the electrode surface 10a and the opposite surface 10c of the first electrode structure 10. An (optional) CMP step performed after the deposition of the insulating layer 18 can be used to planarize the surface of the deposited insulating layer 18 and adjust the desired layer thickness of the insulating layer 18 on the opposite surface 10c of the first electrode structure 10.

With regard to further method steps of the manufacturing method shown in FIGS. 4A to 4C, reference is made to the description of the embodiment shown in FIGS. 3A to 3C.

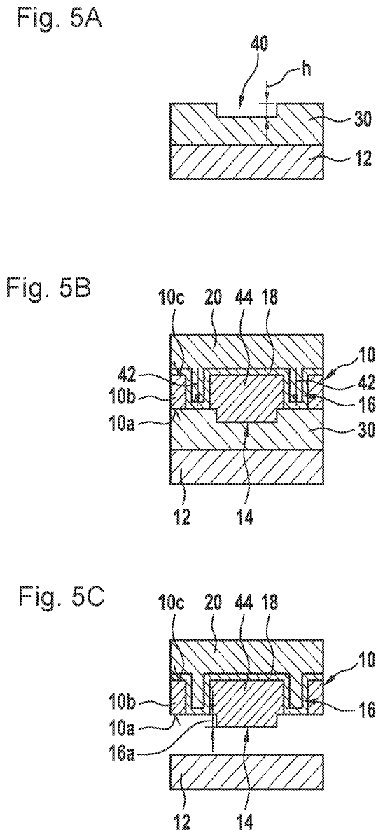

FIGS. 5A to 5c are schematic cross-sections for explaining a third embodiment of the manufacturing method.

In the manufacturing method schematically represented in FIGS. 5A to 5C, the second electrode structure 12 is formed first. Subsequently, at least the sacrificial material layer 30 is deposited on the side of the second electrode structure 12 which is later aligned with the first electrode structure 10. Thereafter, as schematically shown in FIG. 5A, at least one depression 40 is patterned in the sacrificial material layer 30, a maximum depth of the at least one depression 40 being less than a minimum layer thickness of the sacrificial material layer 30. In the manufacturing method described here, the position and shape of the at least one depression 40 also determine the respective future position and the respective future shape of the at least one stop structure 14. Likewise, the maximum depth of the at least one depression 40 in each case defines a later height h of the at least one stop structure 14.

As can be seen in FIG. 5B, at least one electrically conductive material of the future first electrode structure 10 is subsequently deposited on the sacrificial material layer 30, thereby forming the at least one stop structure 14 from the at least one electrically conductive material of the future first electrode structure 10 by filling the at least one depression 40. However, the manufacturing method described here also ensures that, even in the event of a mechanical contact between the at least one stop structure 14 and the second electrode structure 12, a charge transfer between the first electrode structure 10 and the second electrode structure 12 is prevented.

For this reason, in a subsequent method step, at least one separation trench 42, which in each case extends to the sacrificial material layer 30, is patterned through the at least one electrically conductive material of the future first electrode structure 10 such that at least one partial volume 44 made from the at least one electrically conductive material of the future first electrode structure 10, which partial volume is equipped with the at least one stop structure 14, is bordered by the at least one separation trench 42. The patterning of the at least one separation trench 42 can be performed by an etching process which is performed starting at the opposite surface 10c of the first electrode structure 10, which is oriented away from the electrode surface 10a, and proceeds to the sacrificial material layer 30.

In a further method step, the at least one insulating region 16 on the first electrode structure 10 is formed by depositing the at least one electrically insulating material in the at least one separation trench 42. By entirely filling the at least one separation trench 42, it can be ensured that the at least one insulating region 16, which in each case extends from at least the electrode surface 10a to at least the opposite surface 10c, is designed such that the at least one stop structure 14 is in each case (entirely) framed by the at least one insulating region 16. In order to implement the manufacturing method schematically represented in FIGS. 5A to 5C, e.g., silicon nitride, silicon dioxide, silicon oxynitride, silicon carbide, undoped silicon and/or undoped germanium, germanium oxide, germanium nitride, germanium oxynitride, germanium carbide, aluminum oxide and/or a further metal oxide can also be used as the at least one electrically insulating material.

Optionally, in the manufacturing method shown in FIGS. 5A to 5C, the at least one electrically insulating material of the insulating layer 18 can also be first deposited in the at least one separation trench 42 and on at least a subarea of the opposite surface 10c of the first electrode structure 10. A remaining volume of the at least one separation trench 42 can then in each case be filled with the at least one electrically insulating and/or electrically conductive material of the core structure 20, whereby the at least one electrically insulating material that covers at least one partial area of the opposite surface 10c and possibly at least one remaining surface of the opposite surface 10c not yet covered by the insulating layer 18 is also covered by the at least one electrically insulating and/or electrically conductive material of the core structure 20. (However, in an alternative embodiment, the insulating region 16 may also be completely/exclusively filled with the insulating layer 18.)

FIG. 5C shows the finished micromechanical component after at least partial removal of the sacrificial material layer 30. In order to avoid etching the stop structure 14 during the at least partial removal of the sacrificial material layer 30, silicon-rich silicon nitride is also preferred as the at least one electrically insulating material of the insulating layer 18, and silicon dioxide and/or silicon is also preferred as the at least one electrically insulating and/or electrically conductive material of the core structure 20 for the manufacturing method shown in FIGS. 5A to 5C.

With regard to further method steps of the manufacturing method of FIGS. 5A to 5C, reference is made to the description of the embodiment shown in FIGS. 3A to 3C.

By virtue of manufacturing the micromechanical component shown in FIG. 5C comprising the at least one insulating region 16 in each case surrounding the at least one stop structure 14, which insulating region electrically insulates the respective stop structure 14 from a remainder of the first electrode structure 10/its substructure 10b, the at least one stop structure 14 can be made of at least one material having a comparatively high electrical conductivity. Since the at least one stop structure 14 is in each case bordered by the at least one insulating region 16, an elastic stop of the second electrode structure 10 can also be implemented on the at least one stop structure 14. A design of the at least one separation trench 42 and the material properties of the at least one electrically insulating material can be chosen so as to ensure a desired elasticity of the stop of the second electrode structure 12 on the at least one stop structure 14.

All of the micromechanical components described above and the micromechanical components manufactured by means of the manufacturing methods explained above can be used for a sensor or microphone device. For example, such a sensor device may be understood to mean an inertial sensor or a capacitive pressure sensor. Optionally, in all of the micromechanical components described above and the micromechanical components manufactured by means of the manufacturing methods explained above, the first electrode structure 10 or the second electrode structure 12 is a displaceable or deformable electrode structure, e.g., can be designed as a warpable membrane in particular, while the other of the two electrode structures 10 and 12 can be implemented as a “fixed counter electrode,” or also as a displaceable or deformable electrode structure.

In this context, it is expressly noted that the at least one stop structure 14 and the mechanical contact surface need not be formed on/in an area of the first electrode structure 10 and/or the second electrode structure 12 actually used as an electrode. Rather, the at least one stop structure 14 and/or the mechanical contact surface may also be arranged to be electrically insulated from the area of the first electrode structure 10 and/or the second electrode structure 12 actually used as an electrode. Accordingly, the at least one stop structure 14 and/or the mechanical contact surface may also be formed outside the area of the first electrode structure 10 and/or the second electrode structure 12 actually used as an electrode.

1-10 (canceled)

11. A micromechanical component for a sensor or microphone device, comprising:
a first electrode structure and a second electrode structure arranged with respect to one another such that an electrode surface of the first electrode structure is aligned with the second electrode structure;
wherein the first electrode structure and/or the second electrode structure are displaceable and/or warpable such that a distance between the electrode surface of the first electrode structure and the second electrode structure is variable;
wherein at least one substructure of the first electrode structure is entirely made of at least one electrically conductive material, and the electrode surface of the first electrode structure and an opposite surface of the first electrode structure oriented away from the electrode surface are outer surfaces of the substructure and are made of the at least one electrically conductive material;
wherein at least one stop structure protruding from the electrode surface towards the second electrode structure is formed on the first electrode structure such that, in the event of a mechanical contact between the at least one stop structure and the second electrode structure, a charge transfer between the first electrode structure and the second electrode structure is prevented; and
wherein the first electrode structure includes at least one insulating region made of at least one electrically insulating material each extending from at least the electrode surface of the first electrode structure to at least the opposite surface of the first electrode structure, wherein each of the at least one stop structure is bordered by an insulating region of the at least one insulating region.

12. The micromechanical component according to claim 11, wherein the at least one insulating region is entirely made of the at least one electrically insulating material, each having an electrical conductivity of less than 10⁻⁸ S/cm and a resistance of greater than 10⁸ Ω·cm.

13. The micromechanical component according to claim 11, wherein the at least one insulating region is at least partially made of silicon nitride, and/or silicon dioxide, and/or silicon oxynitride, and/or silicon carbide, and/or undoped silicon and/or undoped germanium, and/or germanium oxide, and/or germanium nitride, and/or germanium oxynitride, and/or germanium carbide, and/or aluminum oxide and/or another metal oxide, as the at least one electrically insulating material.

14. The micromechanical component according to claim 11, wherein each insulating region of the at least one insulating region is shaped such that the insulating region at least partially surrounds a core structure made of at least one electrically insulating and/or electrically conductive material.

15. A manufacturing method for a micromechanical component for a sensor or microphone device, the method comprising the following steps:
arranging a first electrode structure and a second electrode structure with respect to one another such that an electrode surface of the first electrode structure is aligned with the second electrode structure, and the first electrode structure and/or the second electrode structure are displaceable and/or warpable such that a distance between the electrode surface of the first electrode structure and the second electrode structure is variable;
wherein at least one substructure of the first electrode structure is entirely made of at least one electrically conductive material, and the electrode surface of the first electrode structure and an opposite surface of the first electrode structure oriented away from the electrode surface are formed as outer surfaces of the substructure and are formed from at the least one electrically conductive material;
wherein at least one stop structure protruding from the electrode surface towards the second electrode structure is formed on the first electrode structure such that, in the event of a mechanical contact between the at least one stop structure and the second electrode structure, a charge transfer between the first electrode structure and the second electrode structure is prevented;
wherein the first electrode structure includes at least one insulating region made of at least one electrically insulating material, which each extends from at least the electrode surface to at least the opposite surface of the first electrode structure, is formed; and
wherein each of the at least one stop structure is bordered by an insulating region of the at least one insulating region.

16. The manufacturing method according to claim 15, further comprising performing the following substeps:
forming the second electrode structure;
depositing at least one sacrificial material layer on a side of the second electrode structure later aligned with the first electrode structure;
depositing at least one electrically conductive material of the future first electrode structure on the sacrificial material layer;
patterning at least one recess through the at least one electrically conductive material of a later formed first electrode structure, each recess of the at least one recess extending into the sacrificial material layer; and
forming the at least one stop structure and the at least one insulating region on the first electrode structure by depositing the at least one electrically insulating material in the at least one recess, thereby forming the at least one stop structure as a projection of the at least one insulating region protruding from the electrode surface towards the second electrode structure.

17. The manufacturing method according to claim 16, wherein the at least one electrically insulating material of the at least one stop structure and the at least one insulating region is first deposited in the at least one recess and on at least a subarea of the opposite surface of the first electrode structure before a respective remaining volume of the at least one recess is filled with at least one electrically insulating and/or electrically conductive material of at least one core structure, wherein the at least one electrically insulating material of the at least one stop structure and the at least one insulating region covering the at least one subarea of the opposite surface is additionally covered by the at least one second electrically insulating and/or electrically conductive material of the at least one core structure.

18. The manufacturing method according to claim 16, wherein the at least one recess is first entirely filled with the at least one electrically insulating material of the at least one stop structure and of the at least one insulating region, which material is additionally deposited on at least a subarea of the opposite surface of the first electrode structure before at least one electrically insulating and/or electrically conductive material is deposited such that the at least one electrically insulating material of the at least one stop structure and the at least one insulating region covering the at least one subarea of the opposite surface is covered by the at least one second electrically insulating and/or electrically conductive material.

19. The manufacturing method according to claim 15, further comprising performing the following substeps:
forming the second electrode structure;
depositing at least one sacrificial material layer on a side of the second electrode structure later aligned with the first electrode structure;
patterning at least one depression in the sacrificial material layer;
depositing at least one electrically conductive material of the later formed first electrode structure on the sacrificial material layer, to form the at least one stop structure by filling the at least one depression with the at least one electrically conductive material of the later formed first electrode structure;
patterning at least one separation trench, each of which extends to the sacrificial material layer through the at least one electrically conductive material of the later formed first electrode structure such that at least one partial volume made from the at least one electrically conductive material of the later formed first electrode structure, which partial volume is equipped with the at least one stop structure, is completely bordered by the at least one separation trench; and
forming the at least one insulating region on the first electrode structure by depositing the at least one electrically insulating material in the at least one separation trench.

20. The manufacturing method according to claim 19, wherein the at least one electrically insulating material of the at least one insulating region is first deposited in the at least one separation trench and on at least a subarea of the opposite surface of the first electrode structure before a remaining volume of the at least one separation trench is in each case filled with at least one electrically insulating and/or electrically conductive material of at least one core structure, wherein the at least one electrically insulating material of the at least one insulating region covering the at least one subarea of the opposite surface is additionally covered by the at least one electrically insulating and/or electrically conductive material of the at least one core structure.
